(19) United States
(12) Patent Application Publication
(10) Pub. No.: US 2016/0056026 A1
(43) Pub. Date: Feb. 25, 2016

(54) PROCESSING APPARATUS

(71) Applicant: CANON ANELVA CORPORATION, Kawasaki-shi (JP)

(72) Inventors: Hidetomo NARADATE, Tokyo (JP); Masahiro SHIBAMOTO, Tokyo (JP)

(73) Assignee: CANON ANELVA CORPORATION, Kawasaki-shi (JP)

(21) Appl. No.: 14/932,289

(22) Filed: Nov. 4, 2015

Related U.S. Application Data
(63) Continuation of application No. PCT/JP2014/005814, filed on Nov. 19, 2014.

(30) Foreign Application Priority Data
Feb. 21, 2014 (JP) 2014-032104

(51) Int. Cl. H01J 37/34

(52) U.S. Cl. CPC H01J 37/3476; H01J 37/3417; H01J 37/3426; H01J 37/345

(57) ABSTRACT

The present invention provides a processing apparatus including a vacuum vessel, a plurality of electrodes arranged in the vacuum vessel, a plurality of power supplies configured to apply potentials to the plurality of electrodes, a detector configured to detect a potential in a process space between a substrate transferred into the vacuum vessel and each of the plurality of electrodes, and a controller configured to control phases of the potentials to be applied to the plurality of electrodes by the plurality of power supplies based on the potential detected by the detector.

This application is a continuation of International Patent Application No. PCT/JP2014/005814 filed on Nov. 19, 2014, and claims priority to Japanese Patent Application No. 2014-032104 filed on Feb. 21, 2014, the entire content of both of which is incorporated herein by reference.

### BACKGROUND OF THE INVENTION

1. Field of the Invention

The present invention generally relates to a processing apparatus for processing a substrate.

2. Description of the Related Art

A processing apparatus (sputtering apparatus) for performing sputtering by using a plurality of targets is used, for example, to deposit a film of a compound containing a plurality of elements, or to perform simultaneous processing of a plurality of substrates or simultaneous processing of the two surfaces of a substrate in a single vacuum processing chamber in the manufacture of a magnetic recording medium. In a processing apparatus like this, the phase of high-frequency power (potential) to be applied from each high-frequency power supply to a target is set (controlled) while monitoring (detecting) the phase (on the high-frequency power supply side) of high-frequency power to be applied to the cathode (target electrode) (see PTLs 1 and 2). Also, this processing apparatus mainly uses a conductive material such as a metal as the target.

PTL 1: International Publication No. 2010/074250 Pamphlet

PTL 2: U.S. Patent Application Publication No. 2004/0089541

### SUMMARY OF THE INVENTION

Recently, however, in the manufacture of a thermally assisted magnetic recording medium, it is necessary to perform sputtering from a plurality of cathodes at the same time by using an insulating material such as MgO as a target in the process of depositing an undercoating layer for controlling the orientation of a magnetic recording layer.

The present inventors have found that when using an insulating material as a target, a phenomenon in which the phase of high-frequency power to be applied from the cathode to a plasma shifts from the phase of high-frequency power set by monitoring the high-frequency power supply side occurs. In this case, the phases of high-frequency power to be applied from the plurality of cathodes to the plasma do not match, so the generation position of the plasma changes, and this makes it difficult to improve the quality such as the uniformity of a film to be deposited on a substrate.

The present invention provides a processing apparatus advantageous in controlling the phases of potentials to be applied to a plurality of electrodes by a plurality of power supplies.

According to one aspect of the present invention, there is provided a processing apparatus including a vacuum vessel, a plurality of electrodes arranged in the vacuum vessel, a plurality of power supplies configured to apply potentials to the plurality of electrodes, a detector configured to detect a potential in a process space between a substrate transferred into the vacuum vessel and each of the plurality of electrodes, and a controller configured to control phases of the potentials to be applied to the plurality of electrodes by the plurality of power supplies based on the potential detected by the detector.

Further features of the present invention will become apparent from the following description of exemplary embodiments (with reference to the attached drawings).

### BRIEF DESCRIPTION OF DRAWINGS

The present invention can provide, for example, a processing apparatus advantageous in controlling the phases of potentials to be applied to a plurality of electrodes by a plurality of power supplies.

FIG. 1 is a schematic plan view showing the arrangement of a processing apparatus as an aspect of the present invention.

FIG. 2 is a schematic sectional view showing an example of the arrangement of a sputtering apparatus.

FIG. 3A is a view showing an example of the waveform of a holder potential.

FIG. 3B is a view showing an example of the waveform of the holder potential.

FIG. 4 is a view showing an example of a change in holder potential as a function of a practical phase difference.

FIG. 5A is a flowchart for explaining control of the phase of a potential to be applied to the cathode of the sputtering apparatus.

FIG. 5B is a flowchart for explaining control of the phase of the potential to be applied to the cathode of the sputtering apparatus.

FIG. 6 is a schematic plan view showing an example of the arrangement of a sputtering apparatus.

FIG. 7 is a schematic sectional view of a vacuum vessel for sputtering.

FIG. 8 is a schematic sectional view showing an example of the arrangement of a sputtering apparatus.

### DESCRIPTION OF THE EMBODIMENTS

Preferred embodiments of the present invention will be explained below with reference to the accompanying drawings. Note that the same reference numerals denote the same members in these drawings, and a repetitive explanation will be omitted.

### First Embodiment

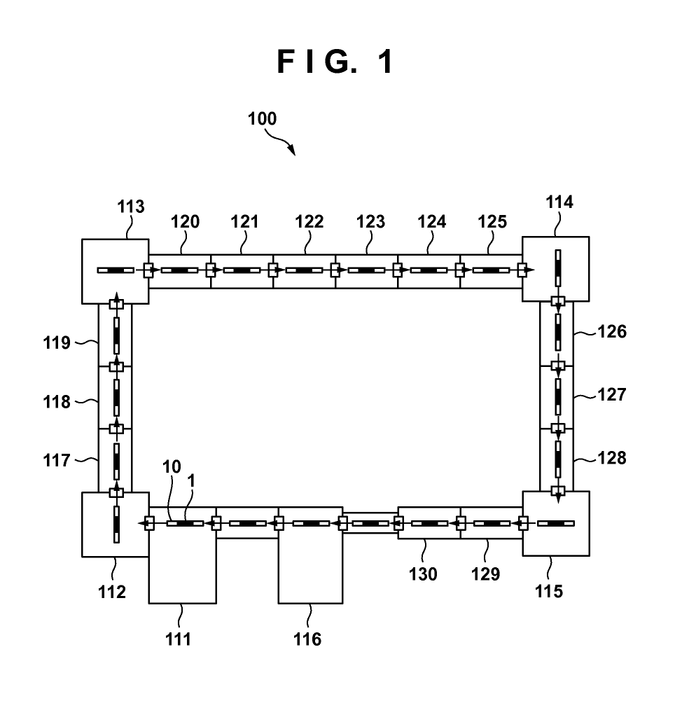

FIG. 1 is a schematic plan view showing the arrangement of a processing apparatus 100 as an aspect of the present invention. The processing apparatus 100 is an apparatus for processing a substrate to be used in a magnetic recording medium or the like. In this embodiment, the processing apparatus 100 is configured as an inline type processing apparatus. The inline type is a method of processing a substrate while transferring the substrate through a plurality of connected chambers. Referring to FIG. 1, a plurality of chambers 111 to 130 are endlessly connected to form a rectangular layout. Each of the chambers 111 to 130 includes an exhaust device and is evacuated by this exhaust device.

In the processing apparatus 100, adjacent chambers are connected via a gate valve. Also, a transfer device for transferring a carrier 10 holding a substrate 1 is connected to each of the chambers 111 to 130 via a gate valve. The transfer device has a transfer path for transferring the carrier 10 upright. The substrate 1 is held in the carrier 10 and transferred along the transfer path. Note that the substrate 1 is a disc-like member made of a metal or glass and having a hole (inner periphery hole) in a central portion.

In this embodiment, the carrier 10 holds two substrates 1 at once and moves upright on the transfer path as described above. The carrier 10 includes a holder which is made of an Al alloy and holds the substrate 1, and a slider which holds the holder and moves on the transfer path. The carrier 10 holds the outer periphery of the substrate 1 by a plurality of holding members (claws) formed on the holder, thereby holding the substrate 1 so that the substrate 1 faces a target, without blocking the processing surface (deposition surface) of the substrate 1.

The chambers 111 to 130 include a processing chamber such as a sputtering chamber. For example, of the chambers 111 to 130, the chamber 111 is a load-lock chamber for performing a process of attaching the substrate 1 to the carrier 10, and the chamber 116 is an unload-lock chamber for performing a process of detaching the substrate 1 from the carrier 10. Each of the chambers 112, 113, 114, and 115 is a chamber including a direction changing device for changing the transfer direction of the carrier 10 (the substrate 1) through 90°. Also, the chamber 117 is an adhesion layer deposition chamber for depositing an adhesion layer on the substrate 1, and each of the chambers 118 to 120 is a soft magnetic layer deposition chamber for depositing a soft magnetic layer on the substrate 1 on which the adhesion layer is deposited. The chamber 121 is a seed layer deposition chamber for depositing a seed layer on the substrate 1 on which the soft magnetic layer is deposited, and each of the chambers 123 and 124 is an interlayer deposition chamber for depositing an interlayer on the substrate 1 on which the seed layer is deposited. Each of the chambers 126 and 127 is a magnetic layer deposition chamber for depositing a magnetic layer on the substrate 1 on which the interlayers are deposited, and the chamber 129 is a protective film deposition chamber for depositing a protective film on the substrate 1 on which the magnetic layers are deposited.

An example of the procedure to be performed on the substrate 1 by the processing apparatus 100 will be explained. First, two unprocessed substrates 1 are attached to the first carrier 10 in the chamber 111. Then, the carrier 10 moves to the chamber 117 for depositing an adhesion layer, and adhesion layers are deposited on the substrates 1. During this process, two unprocessed substrates 1 are attached to the second carrier 10 in the chamber 111.

Subsequently, the first carrier 10 moves in the order of the chambers 118, 119, and 120 for depositing soft magnetic layers, thereby depositing soft magnetic layers on the substrates 1. During this process, the second carrier 10 moves to the chamber 117 for depositing an adhesion layer, adhesion layers are deposited on the substrates 1, and two substrates 1 are attached to the third carrier 10 in the chamber 111. Thus, whenever the first carrier 10 and subsequent carrier 10 move, two substrates 1 are attached to the following carrier 10 in the chamber 111.

Then, the first carrier 10 holding the substrates 1 on which the soft magnetic layers are deposited moves to the chamber 121 for depositing a seed layer, and seed layers are deposited on the substrates 1. After that, the first carrier 10 moves to the chambers 123 and 124 for depositing interlayers, the chambers 126 and 127 for depositing magnetic layers, and the chamber 129 for depositing a protective layer in order, thereby depositing interlayers, magnetic layers, and protective films on the substrates 1.

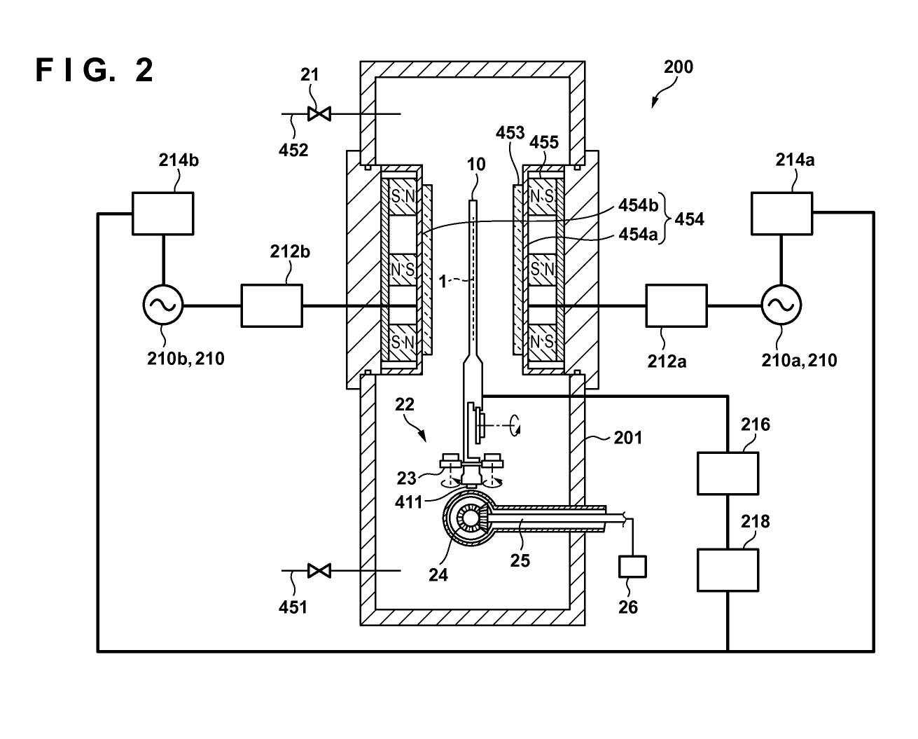

FIG. 2 is a schematic view showing an example of the arrangement of a sputtering (deposition) apparatus 200. That is, FIG. 2 shows a section of the sputtering apparatus 200, which is perpendicular to the transfer direction of the carrier 10. The sputtering apparatus 200 is an arbitrary one of the chambers 117 to 130 (except for the chambers 112 to 114) forming a part of the processing apparatus 100 shown in FIG. 1.

The sputtering apparatus 200 includes a vacuum vessel 201, exhaust system 451, gas supply system 452, cathode 454, and cathode magnet 455. The sputtering apparatus 200 also includes a power supply 210, matching devices 212a and 212b, phase adjusters 214a and 214b, a detector 216, and a controller 218.

The vacuum vessel 201 is partitioned by a gate valve (not shown). The vacuum vessel 201 contains the gas supply system 452 for supplying a process gas into the internal space (process space), a valve 21 for controlling the pressure of the internal space, and a target 453 arranged in the internal space so as to expose a surface to be sputtered. The vacuum vessel 201 also contains the cathode (electrode) 454 as a back board for holding the target 453, the cathode magnet 455 arranged on the rear surface of the target 453, and the power supply 210 for applying (giving) discharge power to the cathode 454.

The vacuum vessel 201 is formed to be horizontally symmetrical with respect to the carrier 10 (the substrate 1). The gas supply system 452 supplies the process gas, and the exhaust system 451 maintains the interior of the vacuum vessel 201 at a predetermined pressure. In this state, the power supply 210 applies electric power to the cathode 454. Consequently, the target 453 is sputtered because discharge occurs, and the sputtered target 453 reaches the substrate 1, thereby depositing a predetermined film on the substrate 1.

A transfer device 22 transfers the carrier 10 movable while holding the substrates 1 along the transfer path. As main constituent elements, the transfer device 22 includes a magnetic screw driving mechanism 411 and guide 23 formed on the chamber side. The magnetic screw driving mechanism 411 includes a spiral magnet shaft 24, a driving shaft 25 for transmitting torque to the spiral magnet shaft 24, and a motor 26 for supplying motive power to the driving shaft 25.

The cathode 454 is an electrode installed in the vacuum vessel. In this embodiment, the cathode 454 includes a pair of cathodes 454a and 454b (a plurality of electrodes) arranged to sandwich (that is, oppose) the substrate 1 (the carrier 10) transferred into the vacuum vessel. An insulating material is formed as the target 453 on each of the cathodes 454a and 454b. Also, a power supply (first power supply) 210a is connected to the cathode (first electrode) 454a via the matching device 212a, and a power supply (second power supply) 210b is connected to the cathode (second electrode) 454b via the matching device 212b. The power supplies 210a and 210b are the power supplies 210 for applying high-frequency power to the cathodes 454a and 454b, respectively. In addition, the phase adjuster 214a is connected to the power supply 210a, and the phase adjuster 214b is connected to the power supply 210b.

The detector 216 detects the potential in the process space between the substrate 1 (the carrier 10) transferred into the vacuum vessel and each of the cathodes 454a and 454b. “The potential in the process space” herein mentioned is the potential output from each of the cathodes 454a and 454b, and includes, for example, the potential in the process space and the potential of a member installed in the process space. In this embodiment, the detector 216 is connected to the holder and detects a potential Vpp of the holder installed in the process space, which is generated by the high-frequency power supplied to the cathodes 454a and 454b.

The controller 218 includes a CPU, memory, and the like, and controls the whole (operation) of the sputtering apparatus 200. In this embodiment, the controller 218 controls the phases of potentials to be supplied from the power supplies 210a and 210b to the cathodes 454a and 454b via the phase adjusters 214a and 214b, based on the potential Vpp detected by the detector 216. The phase adjusters 214a and 214b and controller 218 will collectively be referred to as “a phase controller” hereinafter. Note that an integrated phase controller may also be formed by giving one of the controller 218 and the pair of phase adjusters 214a and 214b the function of the other.

The detector 216 detects at least the potential of (the substrate 1 held by) the holder, and outputs the amplitude of a change in high-frequency voltage flowing into the substrate 1. More specifically, the detector 216 includes a voltmeter (electrode) connected to the holder, a storage unit for storing the measurement value of the voltmeter for a predetermined time or more, and an oscilloscope. The voltmeter is electrically connected to the holder, and the holder is placed in a process position (deposition position) while holding the substrates. Accordingly, the detector 216 can detect (a change in) the potential in the process space during the process. Also, the amplitude of the waveform of the holder potential detected by the detector 216 is regarded as the peak to peak potential (Vpp). Note that the detector 216 need only be capable of detecting the potential in the process space, and is not limited to the form in which the voltmeter is connected to the holder.

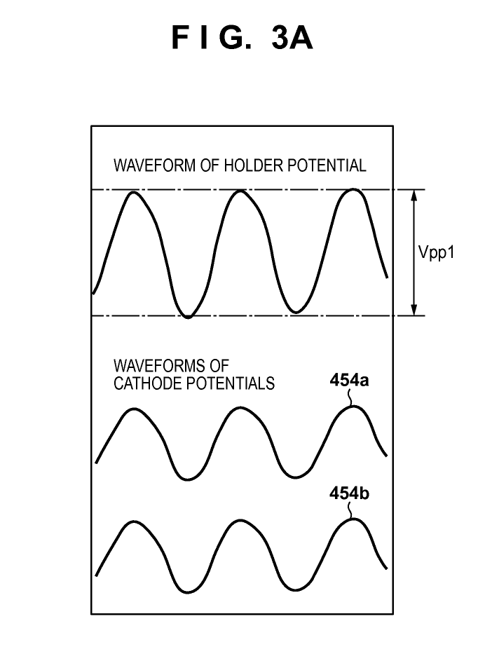

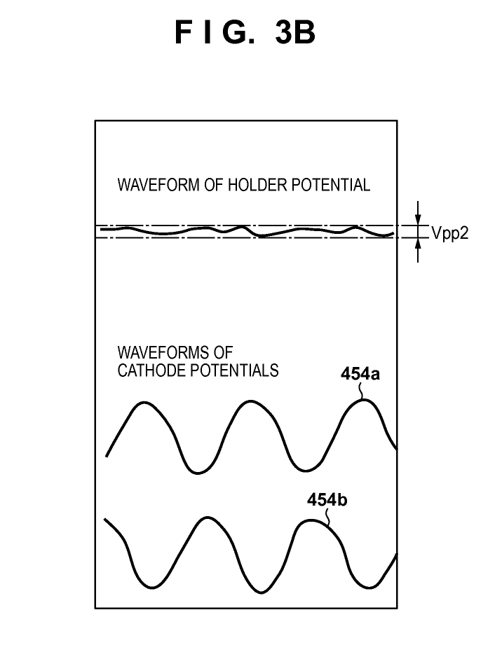

FIG. 3A is a view showing an example of the waveform of the holder potential detected by the detector 216 when the phases of the potentials output from the cathodes 454a and 454b are the same (the phase difference is 0°). FIG. 3B is a view showing an example of the waveform of the holder potential detected by the detector 216 when the phases of the potentials output from the cathodes 454a and 454b are opposite (the phase difference is 180°).

As shown in FIG. 3A, when the phases of the potentials (high-frequency discharges) output from the cathodes 454a and 454b are the same, two identical phases overlap each other in the process position, so the waveform of the holder potential increases. In other words, when the high-frequency discharges have the same phase, a peak to peak potential Vpp1 of the amplitude of the waveform of the holder potential detected by the detector 216 is maximum.

On the other hand, as shown in FIG. 3B, when the phases of the potentials output from the cathodes 454a and 454b are opposite, the waveforms of these potentials cancel out each other in the process position, so the waveform of the holder potential flattens. In other words, when the high-frequency discharges have opposite phases, a peak to peak potential Vpp2 of the amplitude of the waveform of the holder potential detected by the detector 216 is minimum.

Note that as described above, when the high-frequency discharges have “the same phase” or “opposite phases”, the phases of the high-frequency potentials output from the cathodes 454a and 454b are the same or opposite in the position of the holder.

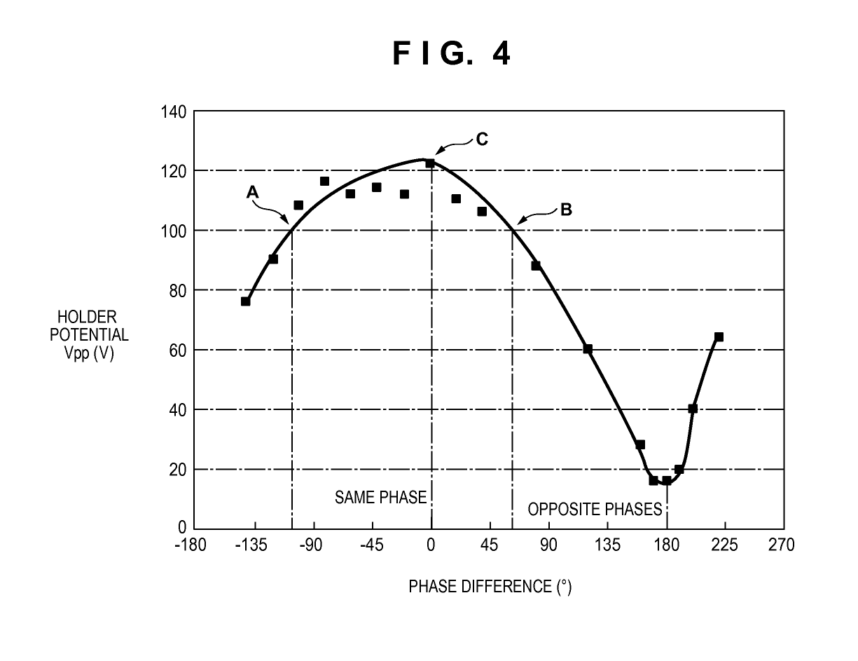

FIG. 4 is a view showing an example of a change in holder potential Vpp as a function of the phase difference between the phase of the potential output from the cathode 454a and the phase of the potential output from the cathode 454b. Referring to FIG. 4, the holder potential Vpp is plotted on the ordinate, and the phase difference is plotted on the abscissa. FIG. 4 shows that the holder potential Vpp has a maximum value when the phases are the same, a minimum value when the phases are opposite, and values corresponding to the phase differences in other cases.

The phase difference will be explained below. Assume that the phase difference between the phase of the potential to be applied from the power supply 210a to the cathode 454a and the phase of the potential to be applied from the power supply 210b to the cathode 454b (that is, the phase difference between the high-frequency powers output from the two high-frequency power supplies) is a set phase difference. Assume also that the phase difference between the phase of the potential output from the cathode 454a and the phase of the potential output from the cathode 454b in the holder position is a practical phase difference.

When using an insulating material as the target 453 as in this embodiment, the target 453 acts as a capacitor. Therefore, the phase difference (set phase difference) between the potentials to be applied to the cathodes 454a and 454b and the phase difference (practical phase difference) between the potentials in the holder position do not match any longer.

As described previously, the holder is electrically connected to the substrate 1 via the holding member, and the detector 216 is practically capable of detecting (the phase difference between) the potentials on the processing surface of the substrate 1. In this embodiment, therefore, the phase difference between the phase of the potential output from the cathode 454a and the phase of the potential output from the cathode 454b, which is equivalent to the phase difference between the potentials (holder potentials) in the holder position, is regarded as the practical phase difference.

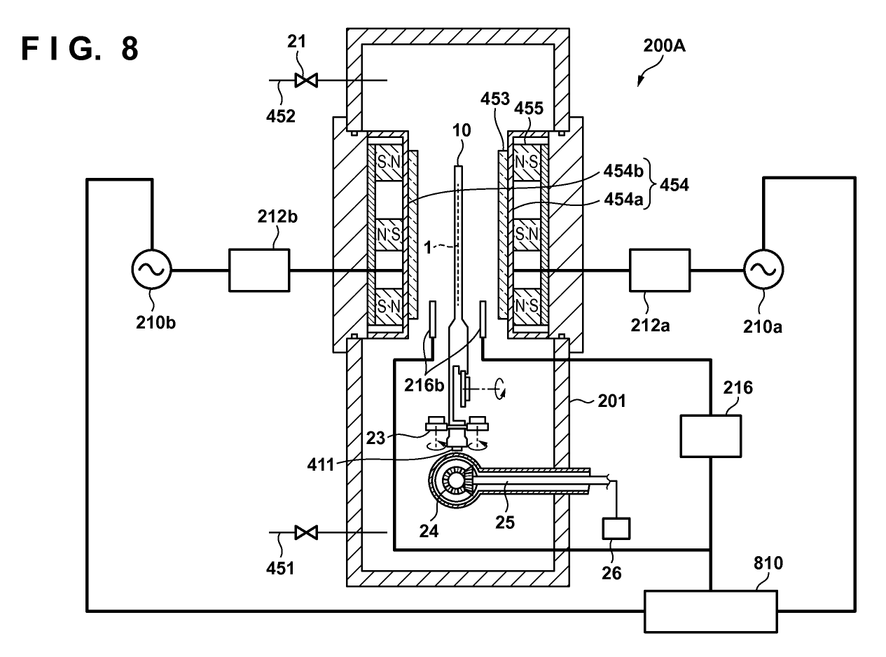

In addition, the holder potential is not limited to the peak to peak potential Vpp, and may also be, for example, a maximum value or minimum value of the potential in the holder position. A voltage is suitable for the potential to be detected by the detector 216. Note that as will be described later with reference to FIG. 8, it is also possible to obtain the phase difference from a voltage detected by an electrode installed in the process space.

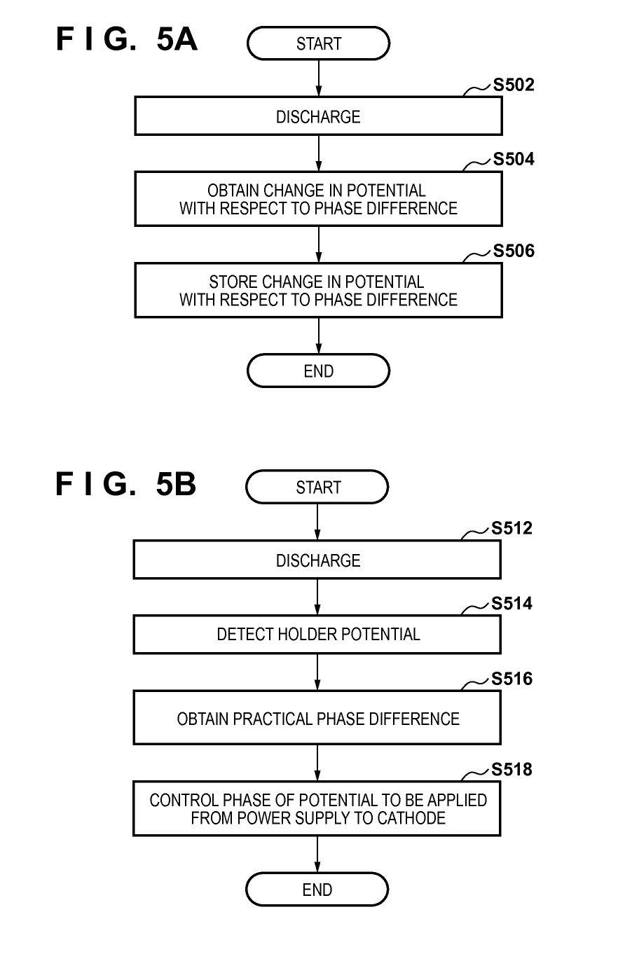

FIGS. 5A and 5B are flowcharts for explaining control (adjustment) of the phases of the potentials to be applied to the cathodes 454a and 454b in the sputtering apparatus 200.

FIG. 5A shows a process of obtaining the relationship as shown in FIG. 4, that is, the relationship between the holder potential (information representing the potential in the process space) and the phase difference between the phase of the potential output from the cathode 454a and the phase of the potential output from the cathode 454b. First, in step S502, discharge is caused between the holder and the cathodes 454a and 454b with no substrate 1 being transferred into the vacuum vessel. In step S504, a change in holder potential with respect to the phase difference between the phase of the potential output from the cathode 454a and the phase of the potential output from the cathode 454b is obtained. More specifically, the holder potential is detected by the detector 216 while changing the phase difference between the phase of the potential output from the cathode 454a and the phase of the potential output from the cathode 454b (the phases of the potentials to be applied to the cathodes 454a and 454b). In step S506, the change in holder potential with respect to the phase difference between the phase of the potential output from the cathode 454a and the phase of the potential output from the cathode 454b, which is obtained in step S504, is stored in the storage unit such as the memory of the controller 218.

By this process shown in FIG. 5A, the relationship between the holder potential and the phase difference between the phase of the potential output from the cathode 454a and the phase of the potential output from the cathode 454b (that is, the relationship shown in FIG. 4) is obtained. In this embodiment, the peak to peak potential (Vpp) as the value of the amplitude of a waveform is used as the holder potential. Accordingly, the phase difference by which the peak to peak potential detected by the detector 216 is maximum corresponds to a practical phase difference of 0° (the same phase). Also, the phase difference by which the peak to peak potential detected by the detector 216 is minimum corresponds to a practical phase difference of 180° (opposite phases).

FIG. 5B shows a process of controlling the phases of the potentials to be applied to the cathodes 454a and 454b. In step S512, discharge is caused between the holder and the cathodes 454a and 454b. In this step, preset initial potentials are applied from the power supplies 210a and 210b to the cathodes 454a and 454b. In step S514, the detector 216 detects the holder potential (that is, the holder potential during discharge). This holder potential detected in step S514 is supplied to the controller 218. In step S516, the phase difference (practical phase difference) between the phase of the potential output from the cathode 454a and the phase of the potential output from the cathode 454b is obtained based on the holder potential detected in step S514. In step S518, the phase of the potential to be applied from the power supply 210a to the cathode 454a and the phase of the potential to be applied from the power supply 210b to the cathode 454b are controlled (adjusted) based on the practical potential difference obtained in step S516. For example, the practical phase difference obtained in step S516 is compared with the change in holder potential (the relationship shown in FIG. 4), which is stored in the storage unit, with respect to the phase difference between the phase of the potential output from the cathode 454a and the phase of the potential output from the cathode 454b. Then, the phases of the potentials to be applied to the cathodes 454a and 454b are controlled such that the phase difference between the phase of the potential output from the cathode 454a and the phase of the potential output from the cathode 454b becomes a predetermined phase difference.

A practical example of the control of the phases of the potentials to be applied to the cathodes 454a and 454b will be explained below. Assume that the high-frequency discharge conditions are that the phases are the same and the set phase difference is 0°, and the holder potential detected by the detector 216 during discharge is 100 V. In this case, the initial set phase difference between the cathodes 454a and 454b is 0°. When 100 V is detected as the holder potential during discharge, however, a phase difference corresponding to a point A or B at which the holder potential is 100 V in the relationship shown in FIG. 4 is the actual phase difference (practical phase difference). Accordingly, the actual phase difference between the phase of the potential output from the cathode 454a and the phase of the potential output from the cathode 454b is −100° or 50°. Referring to FIG. 4, when the phase difference between the cathodes 454a and 454b is the same phase, the holder potential is maximum (a point C). To make the practical phase difference be the same phase, therefore, the controller 218 shifts the set phase difference in the direction of increasing the holder potential via the phase adjusters 214a and 214b. When the holder potential becomes maximum, the practical phase difference becomes the same phase.

In this embodiment, the phase difference is obtained at two points (the points A and B shown in FIG. 4) from the holder potential detected by the detector 216. Accordingly, to obtain a set phase difference by which the holder potential is maximum (in other words, to make the practical phase difference be the same phase), it is necessary to shift to the direction of increasing or decreasing the set phase difference. Therefore, the set phase difference is shifted by a predetermined angle, for example, about 5°, and the holder potential is detected. If the potential has decreased, the set phase difference is shifted in the opposite direction. This makes it possible to shift the set phase difference in a correct direction.

In this embodiment, the relationship between the holder potential and the phase difference between the phase of the potential output from the cathode 454a and the phase of the potential output from the cathode 454b (that is, the relationship shown in FIG. 4) is preobtained. This preobtained relationship is referred to when controlling the phases of the potentials to be applied to the cathodes 454a and 454b. However, the relationship as shown in FIG. 4 is not always necessary if the holder potential is maximum when the practical phase difference is the same phase, and minimum when the practical phase difference is opposite phases. For example, to make the practical phase difference be the same phase, a set phase difference which maximizes the holder potential need only be obtained. Accordingly, it is possible to control the phases of the potentials to be applied to the cathodes 454a and 454b without preobtaining the relationship as shown in FIG. 4. Similarly, to make the practical phase difference be opposite phases, a set phase difference which minimizes the holder potential need only be obtained.

On the other hand, to make the practical phase difference be a predetermined phase difference, it is necessary to preobtain the relationship between the holder potential and the phase difference between the phase of the potential output from the cathode 454a and the phase of the potential output from the cathode 454b (that is, the relationship shown in FIG. 4). Assume that the phase difference (practical phase difference) between the cathodes 454a and 454b is made to be 90°. In this case, the set phase difference must be controlled (adjusted) by referring to the relationship between the holder potential and the phase difference between the phase of the potential output from the cathode 454a and the phase of the potential output from the cathode 454b.

Note that the control of the phases of the potentials to be applied to the cathodes 454a and 454b is generally performed at a timing at which the target 453 is replaced, and used to obtain the discharge conditions. However, it is also possible to perform the control during the process (that is, at all times).

In this embodiment, even when an insulating material is used as the target, it is possible to optimally control the phases of the potentials to be applied from a plurality of power supplies to a plurality of cathodes such that the phase difference between the potentials output from the cathodes becomes a predetermined phase difference. Since this makes it possible to equalize the phases of the potentials to be applied from the plurality of cathodes to a plasma, it is possible to stabilize the plasma generation position, and improve the quality such as the uniformity of a film to be deposited on a substrate.

### Second Embodiment

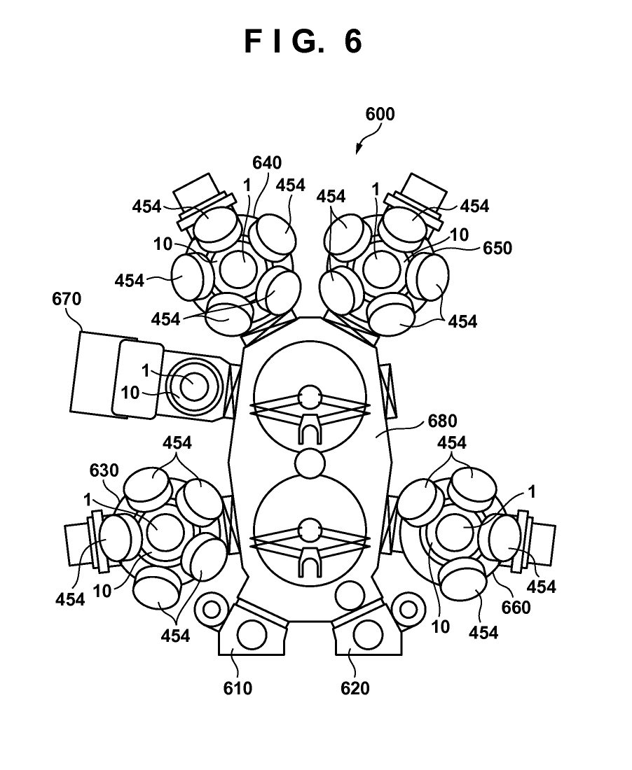

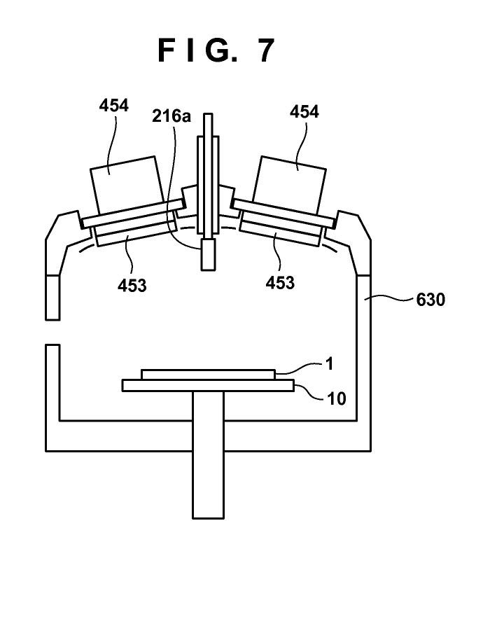

FIG. 6 is a schematic plan view showing an example of the arrangement of a sputtering apparatus 600. The sputtering apparatus 600 includes a chamber 610 which functions as a load-lock chamber, a chamber 620 which functions as an unload-lock chamber, a plurality of vacuum vessels 630 to 670, and a transfer chamber 680. The vacuum vessels 630, 640, 650, and 660 are vacuum vessels for sputtering (deposition). For example, an adhesion layer, soft magnetic layer, seed layer, interlayer, magnetic layer, protective film, and the like are deposited on a substrate in the vacuum vessels 630 to 660. Also, the vacuum vessel 670 is a vacuum vessel for an oxidation process. For example, a metal layer or the like deposited on a substrate is oxidized in the vacuum vessel 670. The chamber 610, chamber 620, and vacuum vessels 630 to 670 are connected by the transfer chamber 680. The transfer chamber 680 incorporates a transfer device for transferring a substrate between the chamber 610, chamber 620, and vacuum vessels 630 to 670.

FIG. 7 is a schematic sectional view of an arbitrary one of the vacuum vessels 630, 640, 650, and 660 for sputtering, for example, the vacuum vessel 630. A holder holding a substrate 1 is transferred into the vacuum vessel 630, and three or more cathodes 454 are arranged to face the substrate 1 (the holder). Also, in the vacuum vessel 630, a potential measurement electrode 216a is installed in the process space as a detector 216 for detecting the potential in the process space. Note that one potential measurement electrode 216a is installed in one position of the process space in this embodiment, but a plurality of potential measurement electrodes 216a may also be arranged in a plurality of positions of the process space. Furthermore, as in the first embodiment, the potential of the holder holding the substrate 1 may also be detected as the potential in the process space. It is also possible to install a potential measurement electrode in each of the process space and holder, and select whether to detect the potential by the potential measurement electrode installed in the process space or holder in accordance with the deposition conditions.

In this embodiment, a case in which the phases of potentials to be applied to the three or more cathodes 454 of the sputtering apparatus 600 are controlled (adjusted) will be explained. First, of the three or more cathodes 454, the phase of a potential to be applied to a first cathode and the phase of a potential to be applied to a second cathode are controlled by the same processing as in the first embodiment. Then, of the three or more cathodes 454, the phase of the potential to be applied to the first cathode and the phase of a potential to be applied to a third cathode are controlled by the same processing as in the first embodiment. Subsequently, of the three or more cathodes 454, the phase of the potential to be applied to the first cathode and the phase of a potential to be applied to a fourth cathode are controlled by the same processing as in the first embodiment. Thus, for all combinations of two cathodes selected from the plurality of cathodes, the phases of the potentials to be applied to the two cathodes are controlled so that the phase difference of potentials output from the two cathodes becomes a predetermined phase difference.

In this embodiment, it is possible to optimally control the phases of the potentials to be applied to three or more cathodes such that the phase difference between potentials output from the cathodes becomes a predetermined phase difference. Since this makes it possible to equalize the phases of the potentials to be applied from the three or more cathodes to plasma, it is possible to stabilize the plasma generation position, and improve the quality such as the uniformity of a film to be deposited on a substrate.

Also, in the sputtering apparatus 600 including the three or more cathodes 454 as in this embodiment, if an insulating material is used as a target for at least one cathode, a phenomenon in which a set phase difference and practical phase difference do not match readily occurs. Accordingly, when using an insulating material as a target for at least one cathode, the phase of the potential to be applied to each cathode is preferably controlled by the same processing as in the first embodiment.

### Third Embodiment

FIG. 8 is a schematic view showing an example of the arrangement of a sputtering apparatus 200A. The sputtering apparatus 200A of this embodiment is the same as the sputtering apparatus 200 shown in FIG. 2 except for the arrangement of a detector 216 for detecting the potential in the process space. Also, the sputtering apparatus 200A includes a phase adjusting unit 810 having the function of the phase adjusters 214a and 214b and the function of the controller 218.

In this embodiment, the detector 216 is configured by arranging a potential measurement electrode 216b for measuring the potential between a holder transferred into the vacuum vessel and a target 453. However, the potential measurement electrode 216b must be so arranged as not to overlap the processing surface (deposition surface) of a substrate 1 held by the holder when viewed from a cathode 454 (the target 453). Also, in this embodiment, two linear potential measurement electrodes 216b are arranged to face each other with the holder being sandwiched between them. However, one potential measurement electrode 216b may also be arranged on the side of one cathode, or near the center between the two cathodes. Furthermore, a ring-like potential measurement electrode 216b may be arranged to surround the holder.

In this embodiment, the two linear potential measurement electrodes 216b are horizontally symmetrically arranged such that the distances from cathodes 454a and 454b are equal. In this embodiment, however, the phases of potentials to be applied to the cathodes 454a and 454b are controlled based on a change in potential caused by the overlap of high-frequency discharge waveforms from the cathodes 454a and 454b. Accordingly, the potential measurement electrode 216b can be arranged anywhere in the vacuum vessel as long as the potential output from each cathode can be detected.

The preferred embodiments of the present invention have been explained above, but the present invention is, of course, not limited to these embodiments, and various modifications and changes can be made within the spirit and scope of the invention. For example, the present invention is applicable (effective) not only to a case in which an insulating material is used as a target, but also to a case in which the phase of a potential output from a cathode (target electrode) shifts from the phase of a potential set on the power supply side. For example, even when a phase shift occurs due to the difference between high-frequency supply path lengths, the present invention can optimally control the phase of a potential output from a cathode.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

What is claimed is:

1. A processing apparatus comprising:
a vacuum vessel;
a plurality of electrodes arranged in the vacuum vessel;
a plurality of power supplies configured to apply potentials to the plurality of electrodes;
a detector configured to detect a potential in a process space between a substrate transferred into the vacuum vessel and each of the plurality of electrodes; and
a controller configured to control phases of the potentials to be applied to the plurality of electrodes by the plurality of power supplies based on the potential detected by the detector,
wherein the controller controls, for all combinations of two electrodes selected from the plurality of electrodes, phases of potentials to be applied to the two electrodes such that a phase difference between potentials output from the two electrodes becomes a predetermined phase difference.

2. A processing apparatus according to claim 1, wherein
the plurality of electrodes include a first electrode and a second electrode,
the plurality of power supplies include a first power supply configured to apply a potential to the first electrode, and a second power supply configured to apply a potential to the second electrode, and
the controller controls a phase difference between a phase of the potential to be applied from the first power supply to the first electrode and a phase of the potential to be applied from the second power supply to the second electrode, such that a phase difference between a phase of a potential output from the first electrode and a phase of a potential output from the second electrode, which is obtained from the potential detected by the detector, becomes a predetermined phase difference.

3. A processing apparatus according to claim 2, wherein the predetermined phase difference is one of 0° and 180°.

4. A processing apparatus according to claim 2, further comprising a storage unit configured to store a relationship between information representing the potential in the process space and the phase difference between the phase of the potential output from the first electrode and the phase of the potential output from the second electrode,
wherein the controller controls the phase difference between the phase of the potential to be applied from the first power supply to the first electrode and the phase of the potential to be applied from the second power supply to the second electrode by referring to the relationship stored in the storage unit.

5. A processing apparatus according to claim 4, wherein the information includes a value of an amplitude of a waveform of the potential in the process space.

6. A processing apparatus according to claim 4, wherein the information is a potential detected by the detector when no substrate is transferred into the vacuum vessel.

7. A processing apparatus according to claim 1, further comprising a holder to be transferred into the vacuum vessel while holding the substrate,
wherein the detector detects a potential of the holder transferred into the vacuum vessel.

8. A processing apparatus according to claim 1, wherein the detector is arranged in a plurality of positions in the process space.

9. A processing apparatus according to claim 1, wherein
each of the plurality of electrodes holds a target, and
at least one of the plurality of electrodes holds an insulating material as the target.
